(19) United States
(12) Patent Application Publication
(10) Pub. No.: US 2013/0207237 A1
(43) Pub. Date: Aug. 15, 2013

(54) METHOD FOR PRODUCING GALLIUM NITRIDE SUBSTRATES FOR ELECTRONIC AND OPTOELECTRONIC DEVICES

(71) Applicants: Claude C.A. Weisbuch, Paris (FR); James S. Speck, Goleta, CA (US)

(72) Inventors: Claude C.A. Weisbuch, Paris (FR); James S. Speck, Goleta, CA (US)

(73) Assignee: The Regents of The University of California, Oakland, CA (US)

(21) Appl. No.: 13/879,183

(22) PCT Filed: Oct. 17, 2011
(86) PCT No.: PCT/US11/56579

§ 371 Date: Apr. 12, 2013

Related U.S. Application Data
(60) Provisional application No. 61/393,767, filed on Oct. 15, 2010.

(51) Int. Cl. H01L 21/762; H01L 29/20

(52) U.S. Cl. CPC H01L 21/76259; H01L 29/2003
USPC 257/615; 438/458

(57) ABSTRACT

A method for separating a III-nitride layer from a substrate. This is done by fabricating a detachment porous region between the III-nitride layer and the substrate through etching. The porous region allows for easy detachment of the III-nitride layer from the substrate. Active layers for electronic and optoelectronic devices can then be grown on the III-nitride layer.

### CROSS REFERENCE TO RELATED APPLICATION

This application claims the benefit under 35 U.S.C. Section 119(e) of the following co-pending and commonly-assigned application:

U.S. Provisional Patent Application Ser. No. 61/393,767, filed on Oct. 15, 2010, by Claude C. A. Weisbuch and James S. Speck, entitled “METHOD FOR PRODUCING GALLIUM NITRIDE SUBSTRATES FOR ELECTRONIC AND OPTOELECTRONIC DEVICES,” attorneys' docket number 30794.391-US-P1 (2011-073-1);

which application is incorporated by reference herein.

### STATEMENT REGARDING FEDERALLY SPONSORED RESEARCH AND DEVELOPMENT

This invention was made with U.S. Government support under Grant No. DE-SC0001009 awarded by the Department of Energy. The U.S. Government has certain rights in this invention.

### BACKGROUND OF THE INVENTION

1. Field of the Invention.

The invention is related to the field of fabricating substrates for electronic and optoelectronic devices.

2. Description of the Related Art.

III-nitride materials are widely used for a number of electronic and optoelectronic devices such as diodes, transistors, light emitting diodes (LEDs), laser diodes, solar cells, etc. The term “III-nitride,” or “group III-nitride,” or “nitride,” or “(Al, Ga, In, B)N,” as used herein is intended to be broadly construed to include respective nitrides of the single species, Al, Ga, In and B, as well as binary, ternary and quaternary compositions of such group III metal species. Accordingly, the term III-nitride comprehends the compounds AN, GaN, and InN, as well as the ternary compounds AlGaN, GaInN, and AlInN, and the quaternary compound AlGaInN, as species included in such nomenclature.

The development of electronic and optoelectronic devices using group III-nitride materials has been hampered by the lack of substrates, in particular GaN substrates, of large size and produced at a low cost. Most III-nitride materials for devices are produced in the form of layers by heteroepitaxial growth on foreign substrates, the most widely used being sapphire and SiC, with Si emerging as a contender for large sized substrates. Due to the lattice mismatch between the substrate and the III-nitride crystals, the III-nitride layers experience strain and dislocation formation which are both detrimental to the performance and quality of III-nitride materials and devices.

The growth also occurs along the c-axis (polar direction) of the III-nitride crystal, which leads to strong polarization-related electric effects. One approach to decreasing the polarization effects in III-nitride materials is to grow the layers in a nonpolar direction of the III-nitride crystal, which includes both the a-axis and the m-axis directions, and which are orthogonal to the c-axis direction.

For some applications, such as LEDs or solar cells, it is, in addition, useful to have structured substrates to better extract internally generated light (LEDs) or to better absorb incident light (solar cells). A good example is provided by LEDs grown on patterned sapphire substrates [see e.g., Yi-Ju Chen et al., Japanese Journal of Applied Physics 49, 020201 (2010)] or embedded photonic crystal LEDs [see e.g., Elison Matioli, et al., Applied Physics Letters 96, 031108 (2010)], or by back plane structured solar cells [see e.g., Hitoshi Sai et al., Applied Physics Letters 93, 143501 (2008)].

In addition, porous semiconductor materials have been developed in the past few years for a number of applications [see e.g., H. Foll et al., J. Nanomaterials, Sp. Iss. 2, article ID 91635, 1(2006)]. Due to the remarkable variations of the fabrication process by controlled etching, they allow fabricators to generate multilayers with variable parameters: for instance, alternate high and low currents in electrochemical dissolution of Si wafers produce layers with alternate high and low porosity; hence, with alternate indices of refraction. This process provides a multilayer which, with layer thicknesses adjusted to a quarter wavelength of the light to be controlled by proper timing of current, acts as a distributed Bragg reflector (DBR) mirror [see e.g., V. Agarwal and J. A. del Rio, Appl. Phys. Lett. 82, 1512 (2003)].

Using porous Si (p-Si) membrane substrates is now a well established practice in the solar cell field [see e.g., Karlheinz Feldrapp et al., Prog. Photovoltaics 11, 105 (2003)]. A separation layer of p-Si is made on a Si bulk crystal. A layer of Si is grown on this layer, and bonded to a support. The Si substrate is then mechanically detached from the layer thanks to the weak porous separation layer. The grown layer on its support is then used and the bulk Si crystal can be reused.

Porous GaN (referred to herein as p-GaN) is mostly used as a growth substrate which can lead to a reduction of defects [see e.g., Hartono et al., Appl. Phys. Lett. 90, 171917 (2007)]. It has been observed that GaN regrown on p-GaN has less dislocations than GaN grown on GaN/sapphire, as there is a better accommodation of the strain by the layer grown on porosities.

Several methods exist for obtaining p-GaN from GaN: etching by a HCl+NH₃ gas mixture; for n-type GaN, electrochemical etching by oxalic acid solution [Yu Zhang et al., Phys. Stat. Sol. B 247, 1713 (2010)]; UV-enhanced electrochemical etching with NaOH solution [H. Hartono et al, J. Electrochemical Society 154, H1004 (2007)]; photo-assisted electrochemical etching in aqueous HF solution [Mynbaeva et al. Inst. Phys. Conf. Ser. 155, 365 (1997)]; and electroless etching [see e.g., D. J. Diaz et al. J. Appl. Phys. 94, 7526 (2003)]. Classically, p-type GaN etching can be obtained by photo-assisted electrochemical (PEC) etching in an HF solution.

A usual way to separate a porous layer from the substrate is by sending a burst of current, which will create a fragile, very high porosity, underlayer. When sidewall etching is pursued long enough, one can also separate a layer from its substrate [Joonmo Park et al., Appl. Phys. Lett. 94, 221907 (2009)].

Alternate growths of GaN on p-GaN with in situ transformation into p-GaN of GaN layers have been proposed [see e.g., Jai-gong Han et al., US Patent Publication No. 2007/0092980].

To obtain regular patterns of the porosities of the etched materials, a mask can be used as an etching mask, such as Al₂O₃.

Nonetheless, there is a need in the art for improved techniques for providing III-nitride substrates for electronic and optoelectronic devices. The present invention satisfies this need.

### SUMMARY OF THE INVENTION

The present invention provides a method for fabricating low cost, large scale, thin film substrates (i.e., membranes) in the III-nitride materials family. The present invention works by introducing a thin “separation” layer of porous material within a thick substrate and then separating a top layer, i.e., a membrane of lower porosity material, from a bottom remaining substrate using the separation layer.

The difference with previous techniques in the field, which relied on GaN grown on sapphire, is that the present invention uses bulk GaN material as a starting material to make the p-GaN, which then is of much higher quality, and by selecting the orientation of the GaN substrate, membranes with any choice of polarity can be generated. The membrane can be used such as when porosity is a desired feature, for instance for light extraction in LEDs or light absorption in solar cells. If porosity is to be suppressed, then the porosity of the membrane can be annealed by adequate thermal or growth treatment, or by growing a thick buffer layer before growth of the device active layer. The membrane can be made up of multilayers of porous layers with variable porosity, which yields a mirror functionality that is useful, for instance, in vertical cavity surface emitting lasers (VCSELs).

### BRIEF DESCRIPTION OF THE DRAWINGS

Referring now to the drawings in which like reference numbers represent corresponding parts throughout:

FIG. 1 schematically represents generating the porosity obtained by etching in a GaN bulk crystal.

FIG. 2 represents electrochemical etching with first a moderate current and then a second stronger current, which leads to larger pores.

FIG. 3 represents electrochemical etching with first a moderate current and then a second even stronger current, which yields to large pores which create a very weakened layer or even lead to the separation of layer from the bulk material.

FIG. 4 shows the separation of a two-porosities layer from the crystal.

FIG. 5 shows the schematics of a layer bonded to a substrate acting as a bottom contact and the overgrown structure to yield a light emitting diode.

FIG. 6 shows the schematics of a multilayer obtained according to the invention.

FIG. 7 is a flowchart illustrating the process steps comprising a method for separating at least one III-nitride layer from a substrate according to one embodiment of the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Overview

The present invention describes how to fabricate a thin “separation” layer of porous material within a thick substrate of III-nitride material, and then separate a top layer, i.e., a membrane of lower porosity material, from a bottom remaining substrate using the thin separation layer that resides between the membrane and the bottom substrate. The membrane can then be used as a growth substrate when porosity is a desired feature. If porosity is to be suppressed, the porosity of the membrane can be annealed either by adequate thermal or growth treatment, or by growing a thick buffer layer before growth of the device active layer. The membrane may be comprised of multiple porous layers with variable porosity. These layers can be used as substrate for the subsequent fabrication of electronic and optoelectronic devices.

### Technical Description

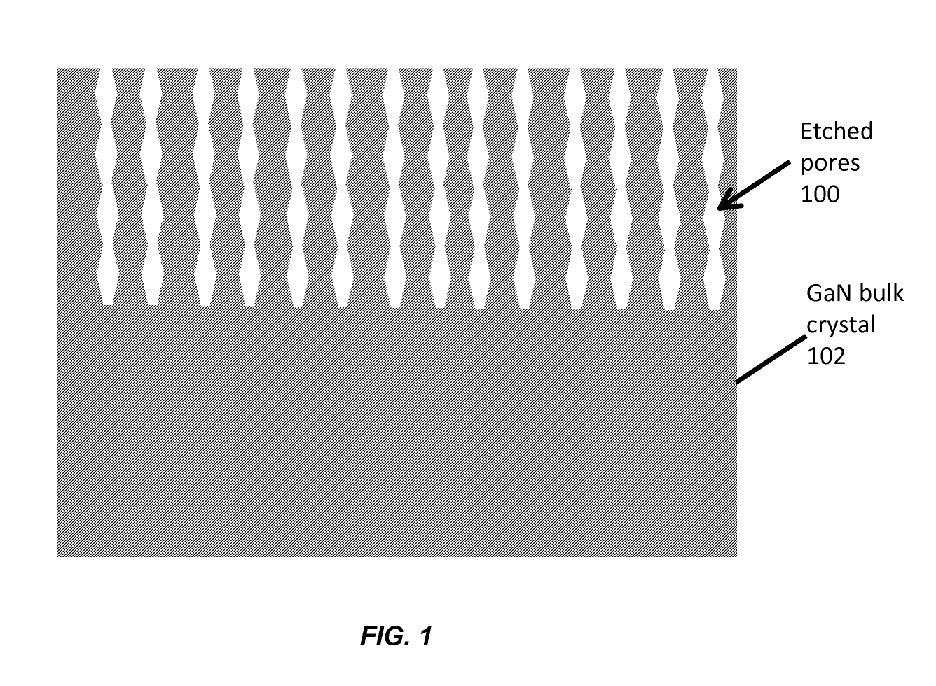

FIGS. 1 to 6 illustrate the main points of the present invention. FIG. 1 schematically represents generating the porosity obtained by etching pores 100 in a GaN bulk crystal 102.

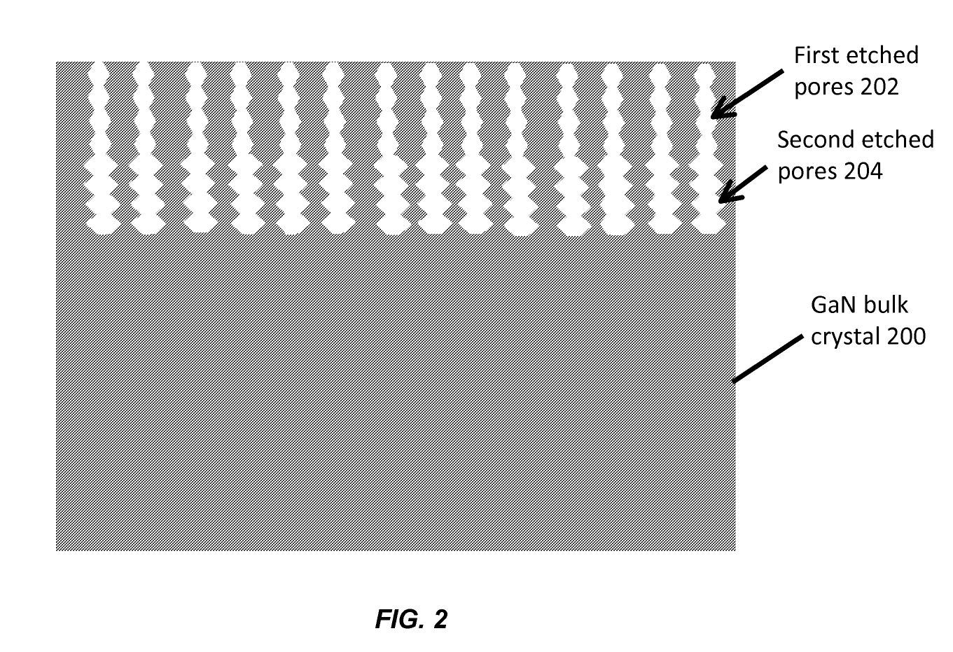

FIG. 2 represents electrochemical etching a GaN bulk crystal 200, with a first moderate current resulting in first etched pores 202, and then with a second stronger current resulting in second etched pores 204. This etching leads to larger pores, i.e., the second etched pores 204 are larger than the first etched pores 202.

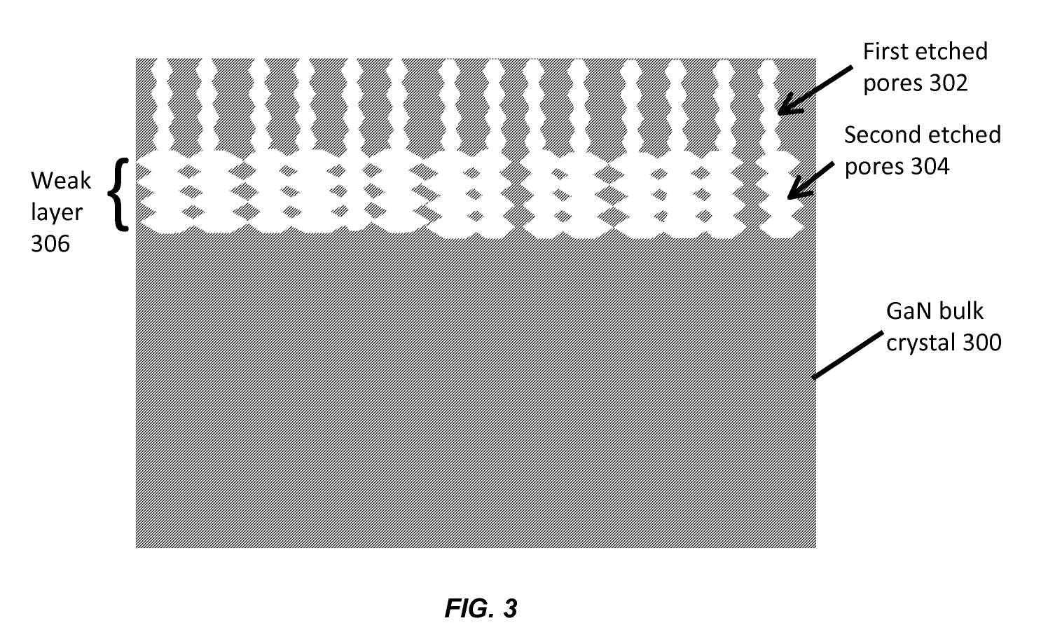

FIG. 3 represents electrochemical etching a GaN bulk crystal 300, with a first moderate current resulting in first etched pores 302, and then with a second even stronger current resulting in second etched pores 304. This etching leads to even larger pores, i.e., the second etched pores 304 are larger than the first etched pores 302, and are even larger than the second etched pores 204 in FIG. 2. Moreover, these even larger second etched pores 304 create a weakened layer 306 that may be used to separate the layers above it from the bulk GaN crystal 300 below it.

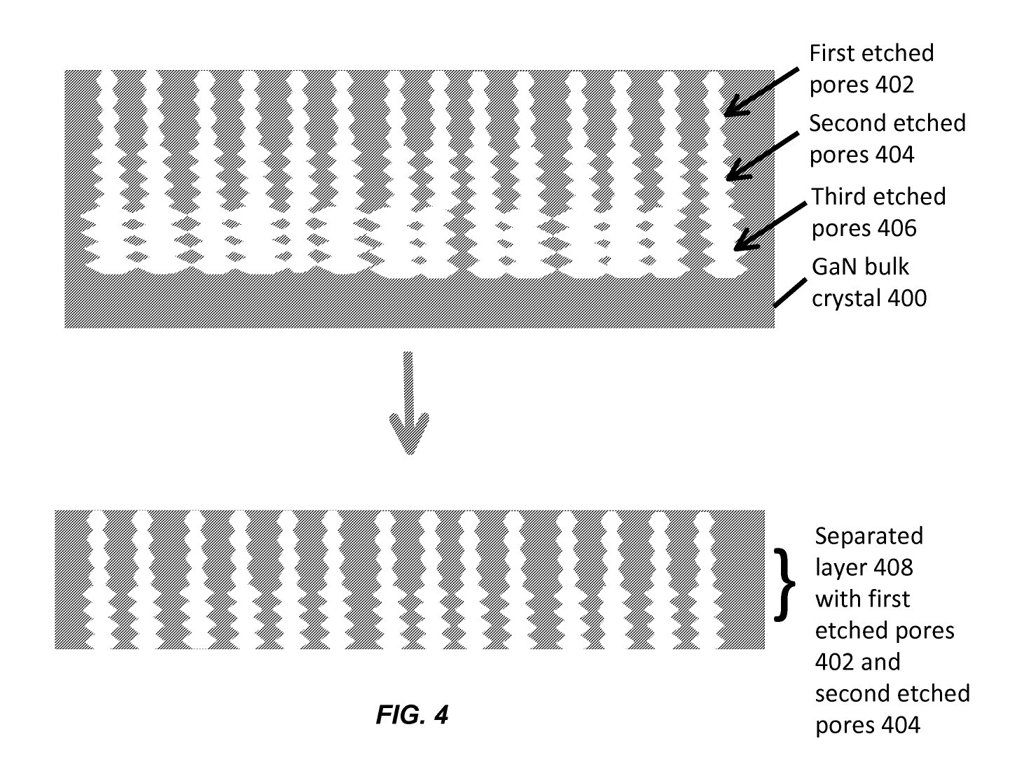

FIG. 4 shows the separation of a two-porosities layer from the crystal, via electrochemical etching of a GaN bulk crystal 400, with a first moderate current resulting in first etched pores 402, then a second stronger current resulting in second etched pores 404 larger than the first etched pores 402, and finally with a third even stronger current resulting in third etched pores 406 larger than the second etched pores 404. In this example, the third etched pores 406 comprise a separation layer 408 that results in the separation of a top layer comprised of the first etched pores 402 and second etched pores 404 from a layer comprised of the pores 408 and the remaining portion of the bulk GaN crystal 400.

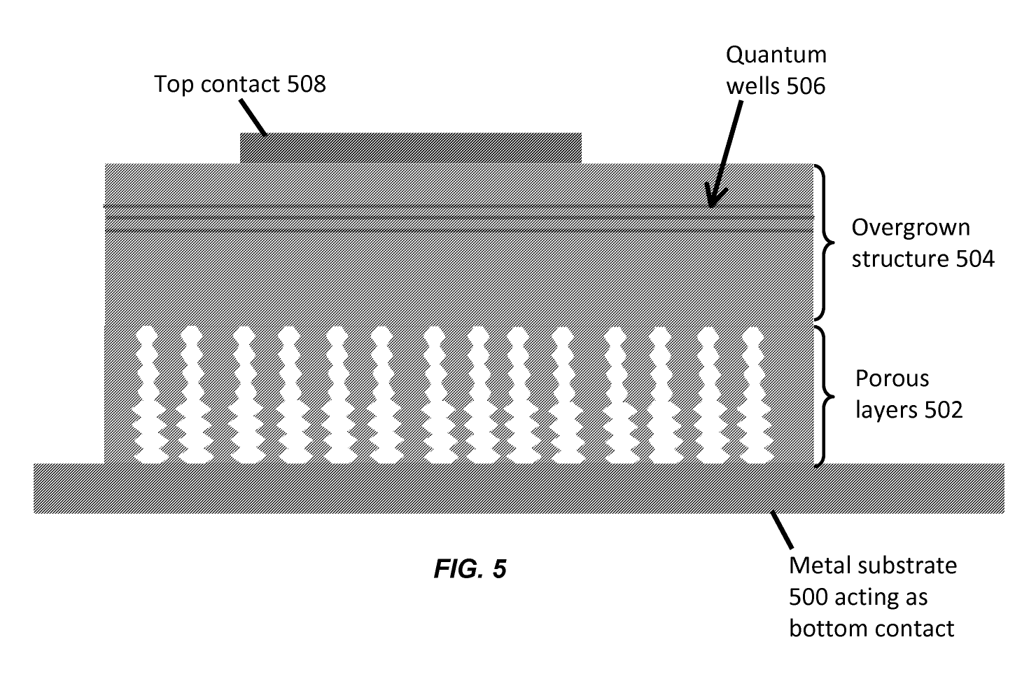

FIG. 5 shows the schematics of a light emitting diode including a metal substrate 500 acting as a bottom contact, one or more porous layers 502, an overgrown structure 504 extending from the top of the porous layers 502 and including quantum wells 506, and a top contact 508 fabricated on a top surface of the overgrown structure 504. In this example, the porous layers 502 are bonded to the substrate 500 acting as the bottom contact, and the overgrown structure 504 is fabricated on top of the porous layers 502.

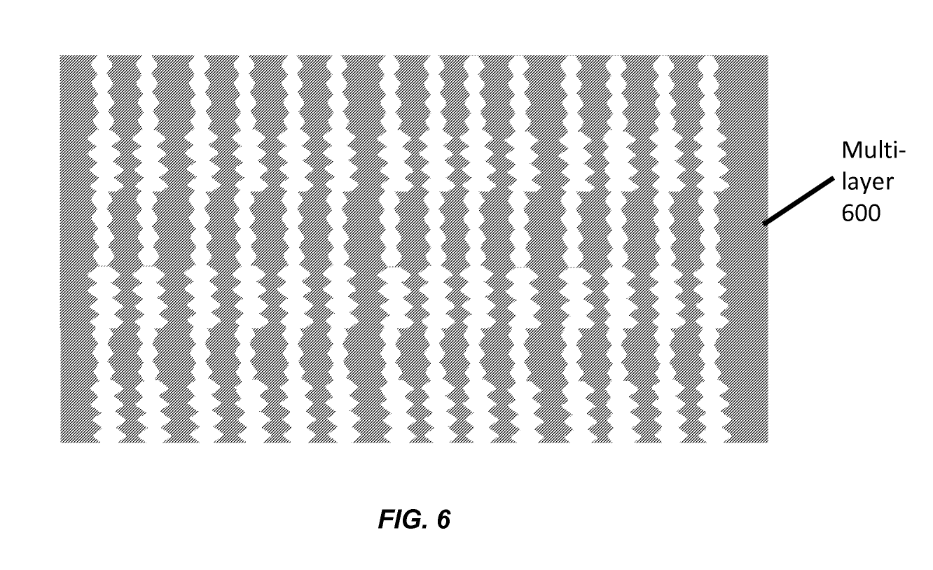

FIG. 6 shows the schematics of a multilayer 600 obtained according to the present invention. In this example, the multilayer 600 contains six distinct porous layers.

### Single Layer Fabrication

For the sake of simplicity, GaN is mentioned in most of the following description, although the present invention applies to all III-nitride materials and their alloys.

The fabrication of single membranes of p-GaN can be done from a bulk material (for instance, realized from methods such as ammonothermal growth, high nitrogen pressure growth, electrochemical solution growth, sublimation method, direct synthesis method, or high vapor phase epitaxy growth) by the usual methods of p-GaN formation in the gas phase or in the liquid phase or a combination of both.

To obtain separation of a p-GaN membrane, a layer of p-GaN with higher porosity is fabricated, for instance, by injecting a higher current in the electrochemical cell.

The p-GaN layer can either be bound to a substrate before separation from the bulk material, or the p-GaN layer can be bound to a substrate after separation from the bulk material.

For some applications (e.g., for LEDs where light extraction is enhanced by the porosity of the material), the thin p-GaN can be used as the template for growth of thin active layers.

For other applications, where higher substrate quality might be desirable, porosity can be diminished before the growth of the active layer of the device in a variety of manners, for instance:
with vapor phase epitaxial growth (e.g., metal-organic chemical vapor deposition (MOCVD), hydride vapor phase epitaxy (HVPE), or molecular beam epitaxy (MBE) regrowth of thick layers), or
with a total or partial collapse of pores through thermal annealing in a suitable atmosphere or regrowth under given conditions leading to preferential regrowth within the pores instead of burying them.

Multiple layers of p-GaN might be desirable for new functions; for instance, for isolation from metal contacts, as shown in FIG. 4. There, a sequence of low porosity layer, higher porosity layer, and ultra high porosity separation layer are etched.

FIG. 5 depicts schematically an LED structure, where the two layer p-GaN 502 has been transferred to a metal substrate 500, which acts as a bottom contact, and an active region 504 has been grown on top of the porous layer 502. The porous layer 502 beneath the active region 504 acts as a light confining layer due to its low index of refraction, therefore diminishing metal optical losses.

FIG. 6 depicts the multilayer 600 as comprising a DBR (Distributed Bragg Reflector), which can be made by (6) sequences of p-GaN etching conditions and which can serve as a high index contrast bottom DBR mirror for a VCSEL (Vertical Cavity Surface Emitting Laser).

As noted above, the layers may be bonded to a substrate, either before or after the detachment from the III-nitride crystal. The choice of substrate depends of the application. As it will have to sustain the high temperatures used during the growth of active device layers, it has a refractory character. It must also have a dilation coefficient compatible with the heating and cooling of III-nitride layers. A typical list can include semiconductors, oxides, refractory metals, such as diamonds, silicon, sapphire, carbides, polycrystalline AN, etc.

After the layer has been separated from the bulk material, one can separate a further layer from the bulk material by starting over the etching process to generate a new separation layer in the bulk material from the bulk material as-is or to regenerate a smooth surface by removing the top roughened porous surface. This can be done by a variety of techniques, such as chemical mechanical polishing (CMP), surface smoothing etching, layer regrowth, etc.

### Process Steps

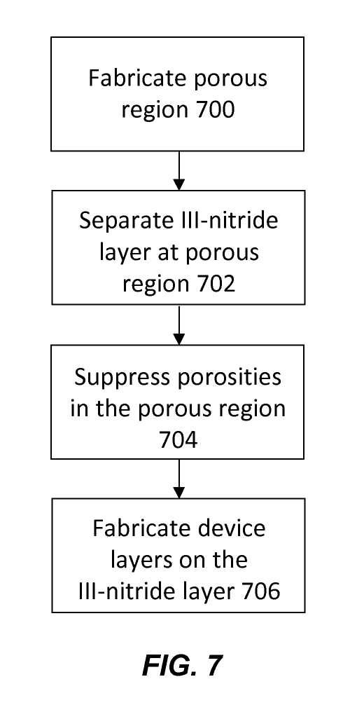

FIG. 7 is a flowchart illustrating the process steps comprising a method for separating at least one III-nitride layer from a substrate according to one embodiment of the present invention, wherein the III-nitride layer is a single layer or is comprised of a plurality of sublayers.

The first step 700 is fabricating a detachment porous region between the III-nitride layer and the substrate through etching. The fabricating step may be performed by: chemically etching the porous region in a vapor or liquid phase; or electrochemically etching the porous region in a liquid phase; or photo-assisted electrochemically etching the porous region in a liquid phase. In one embodiment, the fabricating step is performed by first etching the porous region at a lower porosity, and then etching the porous region at a higher porosity. The result is a porous region that includes two or more sublayers with different porosities, wherein at least one of the sublayers has a higher porosity and is a preferred layer for being separated. Alternatively, these sublayers may form a distributed Bragg reflector.

The second step 702 is separating the III-nitride layer from the substrate at the porous region, wherein the separating step may be performed in situ or ex situ from an etching apparatus. Note that the III-nitride layers or the porous region may be bonded to a substrate before or after being separated. The separating step may be performed by: over-etching the porous region; by applying a mechanical stress to the porous region; by applying a thermal treatment to the porous region; or by applying an optically-assisted process to the porous region.

The third step 704 is suppressing porosities in the porous region at its surface or within its bulk after being separated. This is an optional step, wherein the porosities are suppressed by annealing using a thermal or growth treatment or by growth of a buffer layer on the porous region. One could also suppress remnants of the highly porous detachment layer by usual smoothing techniques, such as chemical mechanical polishing (CMP), surface smoothing etching, layer regrowth, etc.

The fourth step 706 is fabricating one or more device layers on the III-nitride layer, and more specifically, growing one or more active layers on the III-nitride separated layer. This also is an optional step, wherein the active layers form an optoelectronic or electronic device.

The end result of these steps is at least one III-nitride layer separated from a nitride based substrate, and more specifically, an optoelectronic or electronic device embodying such a III-nitride layer.

### REFERENCES

The following references are incorporated by reference herein:

1. Yi-Ju Chen et al., Japanese Journal of Applied Physics 49, 020201 (2010).

2. Elison Matioli, et al., Applied Physics Letters 96, 031108 (2010).

3. Hitoshi Sai et al., Applied Physics Letters 93, 143501 (2008).

4. H. Foll et al., J. Nanomaterials article ID 91635, 1(2006).

5. V. Agarwal and J. A. del Rio, Appl. Phys. Lett. 82, 1512 (2003).

6. Karlheinz Feldrapp et al., Prog. Photovoltaics 11, 105 (2003).

7. Hartono et al., Appl. Phys. Lett. 90, 171917 (2007).

8. Yu Zhang et al., Phys. Stat. Sol. B 247, 1713 (2010).

9. H. Hartono et al, J. Electrochemical Society 154, H1004 (2007).

10. Mynbaeva et al. Inst. Phys. Conf. Ser. 155, 365 (1997).

11. D. J. Diaz et al. J. Appl. Phys. 94, 7526 (2003).

12. Joonmo Park et al., Appl. Phys. Lett. 94, 221907 (2009).

13. Jai-yong Han et al., US Patent Publication No. 2007/0092980.

### Conclusion

This concludes the description of the preferred embodiments of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method for separating at least one III-nitride layer from a substrate, comprising:
fabricating a porous region between the III-nitride layer and the substrate through etching; and
separating the III-nitride layer from the substrate at the porous region.

2. The method of claim 1, wherein the substrate is a binary, ternary, or quaternary compound of the III-nitrides materials family.

3. The method of claim 1, wherein one or more active layers are grown on the III-nitride layer.

4. The method of claim 1, wherein the III-nitride layer is a single layer or is comprised of a plurality of sublayers.

5. The method of claim 1, wherein the fabricating step is performed by chemically etching the porous region in a vapor or liquid phase.

6. The method of claim 1, wherein the fabricating step is performed by electrochemically etching the porous region in a liquid phase.

7. The method of claim 6, wherein the chemically etching step is performed by photo-assisted electrochemically etching the porous region in a liquid phase.

8. The method of claim 1, wherein the fabricating step is performed by etching the porous region at a lower porosity.

9. The method of claim 1, wherein the fabricating step is performed by etching the porous region at a higher porosity after etching the etching the porous region at the lower porosity.

10. The method of claim 9, wherein the porous region includes two or more sublayers with different porosities.

11. The method of claim 10, wherein at least one of the sublayers has a higher porosity and is a preferred layer for being separated.

12. The method of claim 10, wherein the sublayers form a distributed Bragg reflector.

13. The method of claim 1, wherein the separating step is performed in situ or ex situ from an etching apparatus.

14. The method of claim 1, wherein the separating step is performed by over-etching the porous region.

15. The method of claim 1, wherein the separating step is performed by applying a mechanical stress to the porous region.

16. The method of claim 1, wherein the separating step is performed by applying a thermal treatment to the porous region.

17. The method of claim 1, wherein the separating step is performed by applying an optically-assisted process to the porous region.

18. The method of claim 1, wherein the III-nitride layers or the porous region are bonded to a substrate before being separated.

19. The method of claim 1, wherein the III-nitride layers or the porous region are bonded to a substrate after being separated.

20. The method of claim 1, further comprising suppressing porosities in the porous region at its surface or within its bulk after being separated.

21. The method of claim 20, wherein the porosities are suppressed by annealing by a thermal or growth treatment or by growth of a buffer layer on the porous region.

22. At least one III-nitride layer separated from a substrate using the method of claim 1.
